(19) United States
(12) Patent Application Publication
(10) Pub. No.: US 2006/0011297 A1
(43) Pub. Date: Jan. 19, 2006

(54) Semiconductor manufacturing apparatus

(75) Inventor: Yong Jin Kim, Gyeonggi-Do (KR)

Correspondence Address: MARGER JOHNSON & McCOLLOM, P.C., 1030 S.W. Morrison Street, Portland, OR, 97205, US

(73) Assignee: JUSUNG Engineering Co., Ltd., Gwangju-Si (KR)

(21) Appl. No.: 11/181,526

(22) Filed: Jul. 14, 2005

(30) Foreign Application Priority Data
Jul. 15, 2004 (KR) 10-2004-0055209
Jun. 21, 2005 (KR) 10-2005-0053297

(51) Int. Cl. C23F 1/00; C23C 16/00; H01L 21/306

(52) U.S. Cl. 156/345.32; 118/719; 156/345.31

(57) ABSTRACT

Disclosed herein is a semiconductor manufacturing apparatus. The apparatus comprises a transfer module, first and second process modules equipped to adjacent first and second faces of the transfer module while defining an acute angle to the first and second faces of the transfer module, respectively, and a load-lock chamber connected to a third face of the transfer module. The adjacent process modules are disposed parallel to each other. As such, the process modules are close to or in contact with each other on the transfer module, thereby reducing an area occupied by the apparatus without reducing manufacturing efficiency. A source supply unit can be enlarged towards an adjacent face of the adjacent process modules, so that various source materials for forming semiconductor chips can be effectively supplied to the semiconductor manufacturing apparatus through the enlarged source supply unit.

### BACKGROUND OF THE INVENTION

This application claims priority from Korean Patent Application No. 2004-0055209, filed on Jul. 15 2004 and 2005-0053297, filed on Jun. 21, 2005 in the Korean Intellectual Property Office, the contents of which are incorporated by reference in their entirety for all purposes.

1. Field of Invention

The present invention relates to a semiconductor manufacturing apparatus, and more particularly, to a semiconductor manufacturing apparatus, which has process chambers and a transfer chamber efficiently arranged to occupy a smaller area without lowering manufacturing efficiency.

2. Description of the Prior Art

Generally, a semiconductor manufacturing apparatus is used for manufacturing semiconductor chips. In particular, the semiconductor manufacturing apparatus is used for a vapor deposition or sputtering process to deposit a semiconductor layer on a semiconductor substrate, or for an etching or exposing process to form a predetermined pattern on the semiconductor substrate.

FIG. 1 is a schematic view illustrating a conventional semiconductor manufacturing apparatus.

As shown in FIG. 1, the conventional semiconductor manufacturing apparatus comprises a transfer module 10 having a transfer robot arm 45 equipped at the center thereof, a plurality of process modules 30a and 30b (which will also be denoted by reference numeral 30) separated a predetermined distance from each other circumferentially around the transfer module 10 and having predetermined conditions for manufacturing semiconductor chips, and a load-lock chamber 20 equipped around the transfer module 10 to receive semiconductor substrates in a stand-by state for a process or after the process. The semiconductor manufacturing apparatus further comprises a cooling chamber 40 equipped to one face of the transfer module to cool the semiconductor chips.

Each of the process modules 30 comprises a reaction chamber 32 for performing a process of manufacturing the semiconductor chips, a controller 34 for controlling operations of each of the process modules 30, and a source supply unit 36 for supplying an additional source.

Such a semiconductor manufacturing apparatus is disclosed in detail in Korean Patent Laid-open Publication No. 2000-20876 and Korean Utility Model Publication No. 1996-8156.

However, in the conventional semiconductor manufacturing apparatus constructed as described above, the plurality of process modules 30a and 30b are circumferentially located around the transfer module 10 while being separated from each other in a V-shape with respect to the center of the transfer module 10. As a result, the semiconductor manufacturing apparatus occupies a large area, thereby restricting the number of semiconductor manufacturing apparatuses, which can be equipped in a limited space. Thus, the conventional semiconductor manufacturing apparatus has a problem in that a sufficient space must be secured in order to obtain a desired manufacturing efficiency. Moreover, when enlarging the source supply unit corresponding to various process conditions, the area occupied by the semiconductor manufacturing apparatus is also increased. As such, the conventional semiconductor manufacturing apparatus has limitation in enlargement of the source supply unit.

### SUMMARY OF THE INVENTION

The present invention has been made to solve the above problems, and it is an object of the present invention to provide a semiconductor manufacturing apparatus, which has process modules arranged more adjacent to each other around a transfer module, thereby enabling easy enlargement of a source supply unit and reducing a space occupied by the apparatus, that is, an area of the semiconductor manufacturing apparatus, without lowering manufacturing efficiency.

In accordance with one aspect of the present invention, the above and other objects can be accomplished by the provision of a semiconductor manufacturing apparatus, comprising: a transfer module; a first process module and a second process module equipped to a first face and a second face of the transfer module while defining an acute angle to the first face and the second face of the transfer module, respectively, the first face and the second face being adjacent to each other; and a load-lock chamber connected to a third face of the transfer module.

An angle of 10 to 90 degrees is preferably defined between each of the first face and second faces and a longitudinal axis of each process module. Here, the first process module is preferably separated a distance of 30 cm or less from the second process module.

In accordance with another aspect of the present invention, a semiconductor manufacturing apparatus is provided, comprising: a plurality of transfer modules; a first process module and a second process module equipped to a first face and a second face of each transfer module while defining an acute angle to the first face and the second face of each transfer module, respectively, the first face and the second face being adjacent to each other; and a load-lock chamber connected to a third face of each transfer module.

In accordance with yet another aspect of the present invention, a semiconductor manufacturing apparatus is provided, comprising: a transfer module; a first process module and a second process module connected to a first face and a second face of the transfer module while being in parallel to each other, respectively; and a load-lock chamber connected to a third face of the transfer module.

The first process module is preferably separated from the second process module so as to be parallel to the second process module in a direction of a longitudinal axis.

The transfer module preferably has one selected from a circular and a polygonal shape. Additionally, the sum of widths of the first process module and the second process module is preferably equal to or greater than a width of the transfer module. The semiconductor manufacturing apparatus preferably further comprises slit valves between the transfer module and the first process module and second process module and between the transfer module and the load-lock chamber.

Each of the first process module and the second process module preferably comprises a reaction chamber, a gas supply controller for supplying gas to the reaction chamber, a driving controller for driving an associated process module, and a source supply unit for supplying a source material to the reaction chamber.

The first process module is preferably separated a distance of 30 cm or less from the second process module.

In accordance with still another aspect of the present invention, a semiconductor manufacturing apparatus is provided, comprising: a plurality of transfer modules in parallel to each other; a first process module and a second process module connected to a first face and a second face of each transfer module, respectively, and positioned in parallel to each other; and a load-lock chamber connected to a third face of each transfer module.

Preferably, the plurality of the first process modules and the second process modules connected to the plurality of transfer modules are arranged in parallel.

### BRIEF DESCRIPTION OF THE DRAWINGS

The foregoing and other objects and features of the present invention will be more clearly understood from the following detailed description taken in conjunction with the accompanying drawings, in which:

FIG. 1 is a schematic view illustrating a conventional semiconductor manufacturing apparatus;

FIG. 2 is a schematic view illustrating a semiconductor manufacturing apparatus in accordance with one embodiment of the present invention;

FIG. 3 is a diagram illustrating the disposition of process modules to a transfer module in accordance with one embodiment of the present invention;

FIGS. 4a and 4b are diagrams illustrating the structure of the process modules in accordance with one embodiment of the present invention, respectively;

FIGS. 5 to 7 are schematic views illustrating a semiconductor manufacturing apparatus in accordance with another embodiment of the present invention; and

FIGS. 8 and 9 are cross-sectional views illustrating a semiconductor manufacturing apparatus in accordance with other embodiments of the present invention, respectively.

### DESCRIPTION OF THE PREFERRED EMBODIMENTS

Preferred embodiments of the present invention will be described in detail with reference to the accompanying drawings, in which like components are denoted by the same reference numerals. It should be understood that the invention is not limited to the embodiments disclosed herein and can be realized in various modifications or alternatives. It should be apparent for those skilled in the art that the embodiments are disclosed herein for complete understanding of the invention.

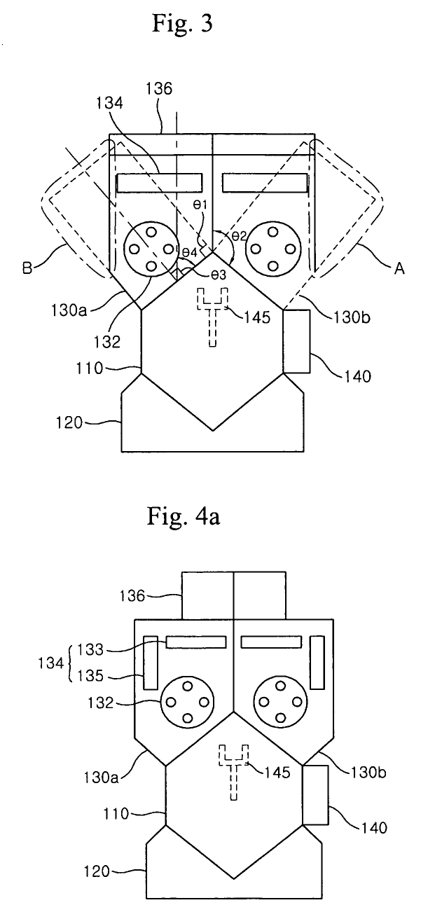

FIG. 2 is a schematic view illustrating a semiconductor manufacturing apparatus according to one embodiment of the invention.

Referring to FIG. 2, the semiconductor manufacturing apparatus of the invention comprises a transfer module 110, and at least two adjacent process modules 130a and 130b (which will also be denoted by reference numeral 130) equipped around the transfer module 110. The semiconductor manufacturing apparatus of the invention may further comprise a cooling chamber 140 for cooling semiconductor substrates, and a load-lock chamber 120 for receiving the semiconductor substrates in a stand-by state for a process or after the process. Optionally, the semiconductor manufacturing apparatus of the invention may further comprise a flat zone aligner (not shown) for aligning a flat zone of the substrate to perform the process, a substrate storage elevator (not shown), and slit valves (not shown) disposed between the transfer module 110 and each of the process modules 130.

The transfer module 110 is located at the center of the semiconductor manufacturing apparatus to load or unload the substrates in the stand-by state within the load-lock chamber 120 to or from the process modules 130a and 130b. For this purpose, the transfer module 110 comprises a transfer robot arm 145 which can load the substrates in the stand-by state into the process modules 130 or can unload the substrates after the process from the process modules 130 to the load-lock chamber 120. Additionally, according to the invention, an outer periphery of the transfer module 110 may have a circular shape, an elliptical shape, or other polygonal shapes, such as a rectangular shape, a pentagonal shape, a hexagonal shape, an octagonal shape, and the like. In the present embodiment, as shown in FIG. 2, the transfer module 110 has a hexagonal outer periphery. The load-lock chamber 120 is equipped along two lower faces of the hexagonal transfer module 110, and the two process modules 130a and 130b are respectively equipped to two upper faces of the hexagonal transfer module 110 facing the two lower faces of the hexagonal transfer module 110. Disposition of the process modules 130 to the transfer module 110 will be described below. The cooling chamber 140 is equipped to another face of the transfer module 110 (at a region between the process modules and the load-lock chamber). Additionally, the transfer module 110 may comprise a plurality of transfer robot arms 145 described above so as to load/unload the substrates into different process chambers 130.

Each of the process modules 130a and 130b comprises a reaction chamber 132 for performing a process for manufacturing semiconductor devices, a controller 134 for controlling operation of the process modules 130a and 130b, and a source supply unit 36 for supplying an additional source according to a reaction process performed in the reaction chamber 132. Each of the process modules 130a and 130b may further comprise an exhausting port. Each of the process modules 130a and 130b may further comprise an RF power generator for generating plasma within the reaction chamber.

Here, a deposition chamber for depositing a predetermined semiconductor layer on at least one substrate or a patterning chamber for forming a predetermined pattern on at least one substrate may be used as the reaction chamber 132. The patterning chamber includes an etching chamber and an ashing chamber, and the deposition chamber includes various chambers depending on types of semiconductor layer. It should be noted that the invention is not limited to these chambers, and that various chambers for manufacturing the semiconductor chips can be applied to the invention. For example, an exposure chamber may be applied to the invention.

In the present embodiment, the reaction chamber 132 is adapted to perform deposition of the semiconductor layers or the pattering process on four substrates at the same time, as shown in FIG. 2. The controller 134 comprises a driving controller for driving the process modules 130a and 130b, and a gas supply controller for supplying gas to the reaction chamber 132. These will be described as follows.

Each of slot valves is connected at one side to the process modules 130 in order to connect the process modules 130 to the transfer module 110, and is connected at the other side to the outer periphery of the transfer module 110.

The process modules 130 are disposed adjacent to each other while being slanted towards each other. The adjacent first and second process modules 130a and 130b may be disposed to have a separation of about 100 cm or less therebetween. In other words, as shown in FIG. 2, the first and second process modules 130a and 130b may be disposed to contact each other or disposed to have a separation of a predetermined distance therebetween. Preferably, the adjacent first and second process modules 130a and 130b are disposed to have a maximum separation of 50 cm or less therebetween while parallel facing each other. More preferably, the separation has a distance of 30 cm or less. Even more preferably, the separation has a distance of 20 cm or less. Such a separation permits easy maintenance of the apparatus. At this time, when the separation between the process modules becomes excessive, a problem of lowering efficiency in area of the semiconductor manufacturing apparatus of the invention can occur.

The disposition and structure of the process modules 130 will be described with reference to drawings.

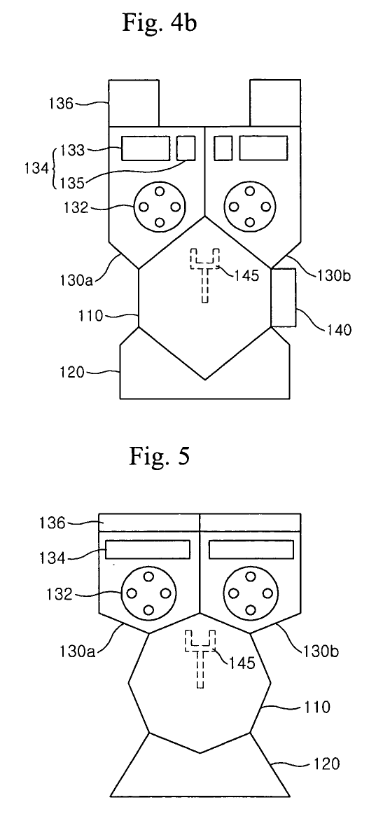

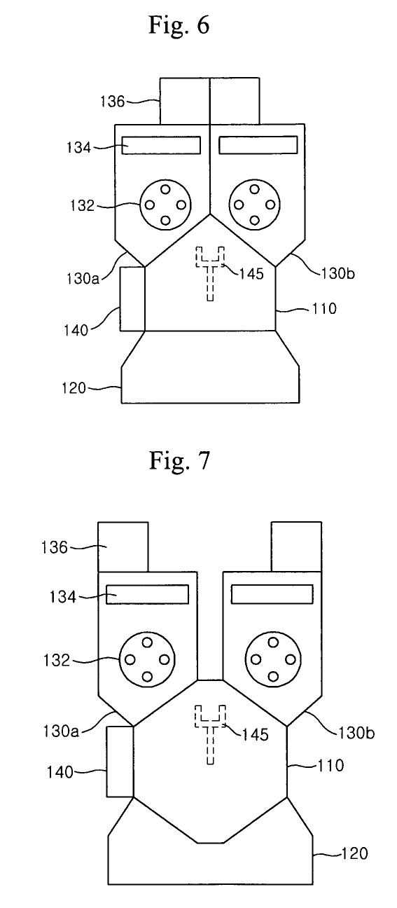

FIG. 3 is a diagram illustrating the disposition of the process modules according to the embodiment of the invention, and FIGS. 4a and 4b are diagrams illustrating the structure of the process modules according to the embodiment, respectively.

Referring to FIG. 3, the conventional process modules are equipped to the peripheral faces of the hexagonal transfer module 110 such that an angle θ3 between a longitudinal axis of each process module and an associated peripheral face of the transfer module 110 is a right angle, thereby allowing distal ends of the process modules to widely spread with respect to the center of the transfer module 110.

On the contrary, according to the invention, the first and second process modules 130a and 130b are equipped to adjacent first and second faces of the transfer module 110 so as to define an acute angle to the first and second faces of the transfer module 110, respectively.

Preferably, an angle θ4 between a longitudinal line, that is, a longitudinal axis, of each of the process modules 130 and an associated face of the transfer module 110 is an acute angle. In this manner, the adjacent process modules 130 are disposed on the peripheral faces of the transfer module 110 so as to be close to each other. Preferably, the angle θ4 between the longitudinal line of each process module 130 and the associated face of the transfer module 110 is in the range of 10 to 90 degrees. More preferably, the angle θ4 is in the range of 35 to 60 degrees. When the angle θ4 between the longitudinal line of each process module 130 and the associated face of the transfer module 110 is less than the range as described above, the first and second process modules 130 overlap, and then cannot be disposed on the faces of the transfer module 110. On the contrary, when the angle θ4 is greater than the range described above, space reduction effect of the invention is lowered. The angle may be varied within the range as described above depending on the shape of the transfer module 110 provided under the process modules. At this time, the load-lock chamber 120 is connected to the third face of the transfer module 110.

According to the invention, the process modules 130 are adjacent to each other, and symmetrically equipped to the two adjacent peripheral faces of the transfer module 110. That is, the adjacent process modules 130a and 130b are disposed in mirror symmetry. For example, an inlet of the first process module 130a for loading the substrates is located on the right, while an inlet of the second process module 130b for loading the other substrates is located on the left. Alternatively, the two adjacent process modules 130 may be disposed so as to contact each other in a direction of an apex defined by the two adjacent peripheral faces of the transfer module 110. Additionally, it is desirable that the first and second process modules 130a and 130b be disposed parallel to each other while being separated from each other in the direction of the longitudinal axis.

Meanwhile, a total width of the first and second process modules 130a and 130b (that is, a transverse width in the plane of FIG. 2) is equal to or greater than a width of the transfer module 110 located under the first and second the process modules 130a and 130b. In this manner, it is possible to mount a substrate having an increased size in the process modules 130a and 130b, and it is also possible to mount a number of substrates in a single chamber. However, an increased size of the transfer module 110 does not permit the size reduction of the apparatus as the effect obtained by the invention.

Additionally, a predetermined angle is defined between the adjacent slit valves connected to the adjacent first and second process modules 130a and 130b. That is, the slit valves are disposed to define an internal angle of 60 to 170 degrees between the adjacent slit valves connected to the adjacent first and second process modules 130a and 130b, respectively. Preferably, the internal angle between the slit valves is in the range of 110 to 150 degrees. As a result, conveyance of the substrates can be easier than the case where the slit valves are disposed in parallel. For obtaining this construction, the first and second process modules 130a and 130b must be disposed adjacent to each other as described above.

Meanwhile, in the conventional apparatus, an angle θ1 between one face of the process module and the peripheral face of the transfer module is about 90 degrees, as described above. However, according to the invention, an internal angle θ2 between an adjacent face of the first and second process modules 130a and 130b and one peripheral face of the transfer module 110 is 90 degrees or greater. Since the first and second process modules 130a and 130b are adjacent to each other, it is not possible to increase the internal angle defined between the adjacent face and the peripheral face without limitation. Accordingly, it is effective to have the internal angle defined in the range of 90 to 165 degrees, and preferably in the range of 100 to 150 degrees.

According to the invention, the process modules 130 may have a pentagonal cross-section, and locations of the controller 134 and the source supply unit 136 are changed from regions A and B of the conventional module. Additionally, locations of pipes and wirings in each process module are changed from those of the conventional module. A location of the substrate supporting member for mounting the substrate is also changed so as to allow the angle defined between the process modules and the robot arm of the transfer module to be adjusted.

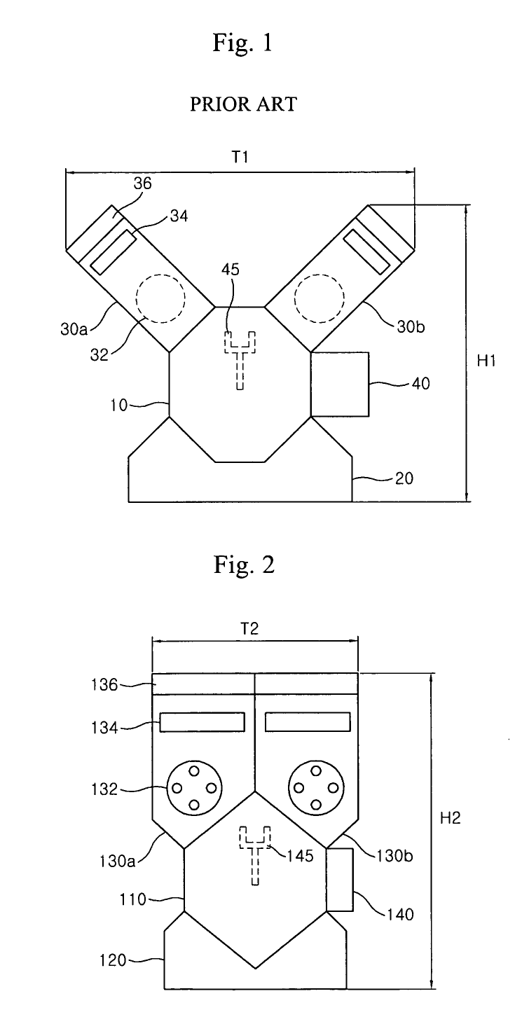

As such, the process modules 130a and 130b are disposed close to each other in the direction of the apex of the transfer module, that is, in the direction of the adjacent face, thereby allowing the space, such as the regions A and B of FIG. 3 to be eliminated. Additionally, assuming that the conventional semiconductor manufacturing apparatus has an area of 1 (T1×H1 in FIG. 1), the semiconductor manufacturing apparatus of the invention has an area of 0.4 to 0.8, thereby allowing the same manufacturing efficiency as that of the conventional semiconductor manufacturing apparatus to be realized in an area 40 to 80% that of the conventional apparatus. More specifically, the conventional semiconductor manufacturing apparatus has T1 of 3,600 mm and H1 of 2,700 mm, whereas the semiconductor manufacturing apparatus of the invention has T2 of 2,000 mm and H2 of 2,800 mm. As described above, assuming that the conventional semiconductor manufacturing apparatus has an area of 100%, the semiconductor manufacturing apparatus of the invention has an area of about 58%, thereby allowing the same manufacturing efficiency as that of the conventional semiconductor manufacturing apparatus to be realized with the smaller area. Additionally, as shown in FIG. 3, since the location of the process chamber 132 in each process module is not changed from that of the conventional process module, it is possible to minimize variation in movement of the transfer robot arm 145. The process modules 130 may have other polygonal cross-sections.

As shown in FIGS. 4a and 4b, the driving controller 135 and the gas-supplying controller 133 constituting the controller 134 may be located in various shapes and structures around the reaction chamber 132. That is, since the driving controller 135 includes various electric circuits and sensors, and the gas supplying controller 133 includes various valves and pipes, arrangement of the driving controller 135 and the gas supplying controller 133 is not limited to a particular arrangement, and can be changed depending on characteristics and objects of the apparatus. As described above, the driving controller 135 and the gas supplying controller 133 are disposed in mirror symmetry in each of the adjacent process modules 130a and 130b, and thus, the various components such as valves, pipes and wirings in each of the process modules are preferably arranged in mirror symmetry.

According to the invention, the source supply unit 136 can be enlarged in the direction of the adjacent face, thereby enabling various source materials for the semiconductor chips to be effectively supplied to the semiconductor manufacturing apparatus therefrom. The source supply unit 136 can be changed in location from an edge of the first and second process modules 130a and 130b to a region adjacent to the adjacent face or away from the adjacent face. Various processes can be performed in a single process module 130 by maximizing an ability of the source supply unit 136 to be enlarged.

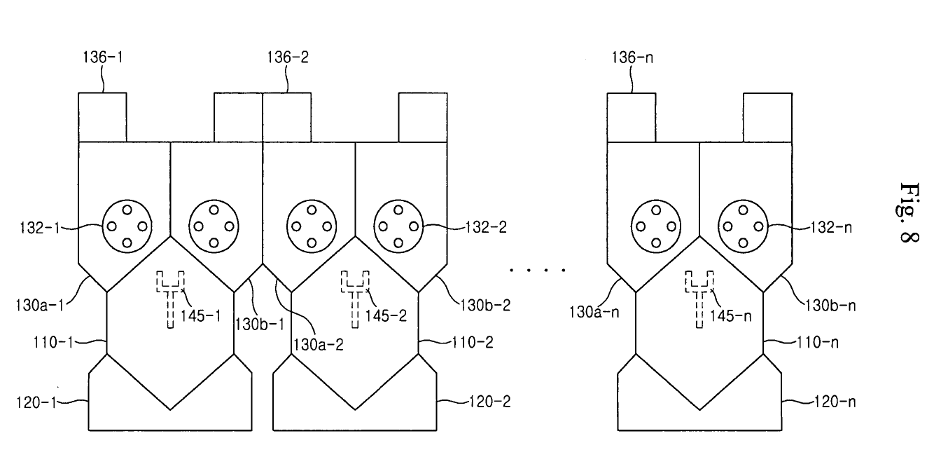

FIGS. 5 to 7 are schematic views illustrating a semiconductor manufacturing apparatus in accordance with other embodiments of the invention.

As shown in FIGS. 5 to 7, the semiconductor manufacturing apparatus in accordance with present embodiments comprises a pentagonal or octagonal transfer module 110, first and second process modules 130a and 130b connected to first and second faces of the transfer module 10 while being parallel to each other, and a load-lock chamber 120 connected to a third face of the transfer module 110.

As shown in FIG. 5, the first and second process modules 130a and 130b are disposed adjacent to each other on adjacent first and second faces of the octagonal transfer module so as to face each other. At this time, the adjacent faces of the first and second process modules 130a and 130b contact each other. Alternatively, as shown in FIG. 6, the first and second process modules 130a and 130b may be disposed on two adjacent peripheral faces of the pentagonal transfer module 110, and positioned in parallel to each other. Alternatively, as shown in FIG. 7, the first and second process modules 130a and 130b may be disposed on two adjacent peripheral faces of the octagonal transfer module 110, and parallel face each other. At this time, a gap between the first and second process modules 130a and 130b parallel facing each other is preferably 1 m or less. More preferably, the gap is 30 cm or less.

Other structures of the semiconductor manufacturing apparatus of the present embodiments are the same as those of the embodiment as illustrated in FIG. 3.

As such, the semiconductor manufacturing apparatus of the invention is not limited in terms of the shape of the transfer module as well as kinds and functions of the process chamber. Additionally, the semiconductor manufacturing apparatus of the invention allows the same productivity as that of the conventional semiconductor manufacturing apparatus in an area that is only 60% that of the conventional semiconductor manufacturing apparatus, and also allows various processes to be performed in a single process chamber.

According to the invention, the pluralities of process modules and transfer modules can be disposed in a line, so that a number of process modules can be disposed in a limited space. With regard to this, a description will be given with reference to the drawings, in which repetitive description will be omitted hereinafter.

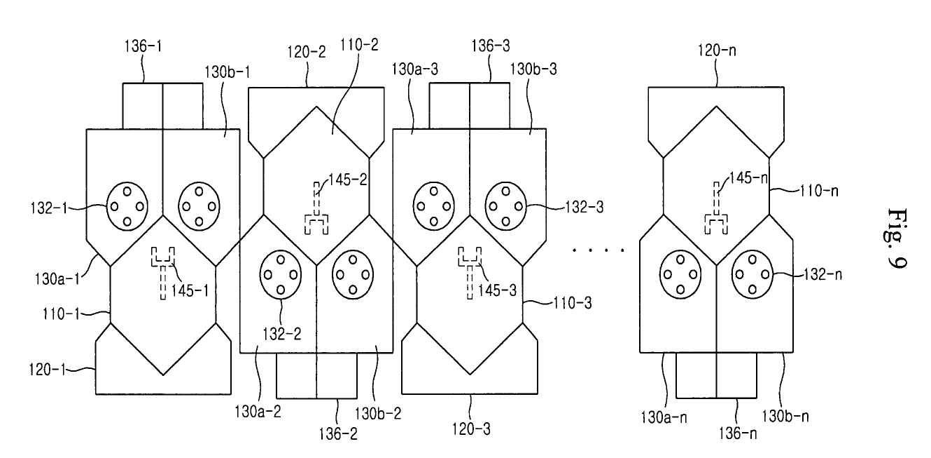

FIGS. 8 and 9 are cross-sectional views illustrating a semiconductor manufacturing apparatus in accordance with other embodiments of the invention, respectively. Referring to FIGS. 8 and 9, a plurality of transfer modules 110-1 to 110-n is disposed in a line, in which each transfer module has at least two process modules 130a-1 to 130a-n and 130b-1 to 130b-n connected thereto. That is, the semiconductor manufacturing apparatus of the present embodiment comprises: the plurality of transfer modules 110-1 to 110-n separated from each other; first and second process modules 130a-1 to 130a-n and 130b-1 to 130b-n respectively disposed on respective adjacent first and second faces of the transfer modules 110-1 to 110-n while defining an acute angle to the first and second faces of the transfer modules, respectively; and load-lock chambers 120-1 to 120-n connected to respective third faces of the transfer modules 110-1 to 110-n.

At this time, the first and second process modules 130a-1 to 130a-n and 130b-1 to 130b-n are preferably equipped to the respective first and second faces of the plurality of transfer modules 110-1 to 110-n, and positioned in parallel to one another.

Here, preferably, with the plurality of transfer modules 110-1 to 110-n sequentially disposed in the apparatus, the first and second process modules 130a-1 and 130b-1 connected to one transfer module 110-1 are adjacent to or contact the other process modules 130a-2 and 130b-2 connected to the next transfer module 110-2. More preferably, the process modules are disposed so as to be parallel to each other. That is, as shown in FIG. 8, the 1st to nth transfer modules 110-1 to 110-n having the adjacent first and second process modules 130a-1 to 130a-n and 130b-1 to 130b-n connected thereto are successively arranged such that the second process module 130b-1 of the first transfer module 110-1 is parallel to the first process module 130a-2 of the second transfer module 110-2.

Additionally, for convenience of maintenance, source supply units 136-1 to 136-n may be disposed in such a manner that, for example, the source supply units 136-1 and 136-2 are disposed to opposite ends of the first and second process modules 130a-1 and 130b-1 connected to one transfer module 110-1. Alternatively, the source supply unit 136-1 of the second process module 130b-1 and the source supply unit 136-2 of the first transfer module 130a-2 may be commonly used in a state of the second process module 130b-1 of the first transfer module 110-1 being disposed to contact the first process module 130a-2 of the second transfer module 110-2.

In this manner, a space for disposing the modules can be remarkably reduced even though the pluralities of modules are disposed, and more arrangements of modules can be secured in the limited space in comparison to the prior art. That is, assuming the width of the conventional apparatus is 1, the width of the apparatus of the invention is in the range of 0.6 to 0.95. Accordingly, for example, a length of 10 m is required for successively disposing five transfer modules having the conventional process modules connected thereto, respectively. However, according to the invention, if the apparatus of the invention is reduced about 20% in width in comparison to the conventional apparatus, a length of 8 m is sufficient for successively arranging the five transfer modules having the process modules connected thereto, respectively. That is, it is possible to arrange six transfer modules within the length of 10 m, thereby remarkably reducing the space for arranging the plurality of modules, and allowing more arrangements of modules in the limited space in comparison to the prior art.

Meanwhile, although the plurality of load-lock chambers 120-1 to 120-n are illustrated as being separated from each other in the drawings, the present invention is not limited to this construction. Alternatively, the adjacent load-lock chambers 120-1 to 120-n may be close to and/or in contact with each other.

According to the invention, the process modules and the transfer modules may be arranged in other manners. For example, in FIG. 8, adjacent pairs of the process modules 130a-1 to 130a-n and 130b-1 to 130b-n connected to the transfer modules 110-1 to 110-n are arranged in vertical symmetry. That is, the plurality of process modules is successively arranged on the transfer modules 101-1. On the contrary, in FIG. 9, adjacent pairs of the process modules 130a-1 to 130a-n and 130b-1 to 130b-n connected to the transfer modules 110-1 to 110-n may be arranged in horizontal symmetry.

The transfer modules 110-1 to 110-n having the adjacent pairs of first and second process modules 130a-1 to 130a-n and 130b-1 to 130b-n connected thereto are successively arranged in such a manner that the adjacent pairs of first and second process modules 130a-1 to 130a-n and 130b-1 to 130b-n are alternately disposed up and down. More specifically, the plurality of process modules 130a-1 to 130a-n and 130b-1 to 130b-n and transfer modules 110-1 to 110-n are arranged in such a manner that, for example, the first and second process modules 130a-1 and 130b-1 of the first transfer module 110-1 are disposed upwardly, the first and second process modules 130a-2 and 130b-2 of the second transfer module 110-2 are disposed downwardly, and then the first and second process modules 130a-3 and 130b-3 of the third transfer module 110-3 are disposed upwardly again.

As a result, a sufficient space for maintenance of the apparatus can be secured at both sides of the process modules 130a-1 to 130a-n and 130b-1 to 130b-n connected to the transfer modules 110-1 to 110-n.

As apparent from the above description, according to the invention, process modules are close to or in contact with each other on a transfer module, thereby reducing an area occupied by the semiconductor manufacturing apparatus without reducing manufacturing efficiency.

Additionally, the source supply unit can be enlarged towards an adjacent face of the adjacent process modules, so that various source materials for forming semiconductor chips can be supplied to the semiconductor manufacturing apparatus through the enlarged source supply unit.

Additionally, various processes can be performed in a single process module.

It should be understood that the embodiments and the accompanying drawings as described above have been described for illustrative purposes and the present invention is limited by the following claims. Further, those skilled in the art will appreciate that various modifications, additions and substitutions are allowed without departing from the scope and spirit of the invention as set forth in the accompanying claims.

1. A semiconductor manufacturing apparatus, comprising:
a transfer module;
a first process module and a second process module equipped to a first face and a second face of the transfer module while defining an acute angle to the first face and the second face of the transfer module, respectively, the first face and the second face being adjacent to each other; and
a load-lock chamber connected to a third face of the transfer module.

2. The apparatus according to claim 1, wherein an angle of 10 to 90 degrees is defined between each of the first face and second faces and a longitudinal axis of each process module.

3. The apparatus according to claim 2, wherein the first process module is separated a distance of 30 cm or less from the second process module.

4. A semiconductor manufacturing apparatus, comprising:
a plurality of transfer modules;
a first process module and a second process module equipped to a first face and a second face of each transfer module while defining an acute angle to the first face and the second face of each transfer module, respectively, the first face and the second face being adjacent to each other; and
a load-lock chamber connected to a third face of each transfer module.

5. A semiconductor manufacturing apparatus, comprising:
a transfer module;
a first process module and a second process module connected to a first face and a second face of the transfer module while being in parallel to each other, respectively; and
a load-lock chamber connected to a third face of the transfer module.

6. The apparatus according to claim 5, wherein the first process module is separated from the second process module so as to be parallel to the second process module in a direction of a longitudinal axis.

7. The apparatus according to claim 5, wherein the transfer module has one selected from a circular and a polygonal shape.

8. The apparatus according to claim 5, wherein the sum of widths of the first process module and second process module is equal to or greater than a width of the transfer module.

9. The apparatus according to claim 5, further comprising: slit valves between the transfer module and the first process module and second process module and between the transfer module and the load-lock chamber.

10. The apparatus according to claim 5, wherein each of the first process module and the second process module comprises:
a reaction chamber;
a gas supply controller for supplying gas to the reaction chamber;
a driving controller for driving an associated process module; and
a source supply unit for supplying a source material to the reaction chamber.

11. The apparatus according to claim 5, wherein the first process module is separated a distance of 30 cm or less from the second process module.

12. A semiconductor manufacturing apparatus, comprising:
a plurality of transfer modules in parallel to each other;
a first process module and a second process module connected to a first face and a second face of each transfer module, respectively, and positioned in parallel to each other; and
a load-lock chamber connected to a third face of each transfer module.

13. The apparatus according to claim 12, wherein the plurality of the first process modules and the second process modules connected to the plurality of transfer modules are parallel arranged.
